(19) United States
(12) Patent Application Publication
(10) Pub. No.: US 2011/0146577 A1
(43) Pub. Date: Jun. 23, 2011

(54) SHOWERHEAD WITH INSULATED CORNER REGIONS

(75) Inventors: SUHAIL ANWAR, San Jose, CA (US); John M. White, Hayward, CA (US); Soo Young Choi, Fremont, CA (US); Gaku Furuta, Sunnyvale, CA (US); Shinichi Kurita, San Jose, CA (US); Carl Sorenson, Morgan Hill, CA (US); Robin L. Tiner, Santa Cruz, CA (US)

(73) Assignee: APPLIED MATERIALS, INC., Santa Clara, CA (US)

(21) Appl. No.: 12/975,708

(22) Filed: Dec. 22, 2010

Related U.S. Application Data
(60) Provisional application No. 61/289,392, filed on Dec. 22, 2009.
(60) Provisional application No. 61/301,205, filed on Feb. 4, 2010.

(51) Int. Cl. C23C 16/455; C23C 16/458; C23C 16/50; B05B 1/14

(52) U.S. Cl. 118/723 R; 239/548

(57) ABSTRACT

Embodiments of the present invention generally relate to a gas distribution showerhead having insulated corner regions to reduce arcing and improve deposition uniformity control. In one embodiment, the gas distribution showerhead is formed of a conductive material with material from the corner regions removed. Corner members formed substantially in the shape of the removed portion of corner regions are attached to the conductive showerhead. The corner members may be made of a material having electrical insulating properties, such as a ceramic or insulating polymer.

### CROSS-REFERENCE TO RELATED APPLICATIONS

This application claims benefit of U.S. Provisional Application Ser. No. 61/289,392, filed Dec. 22, 2009 (Attorney Docket No. APPM/14998L), which is incorporated by reference in its entirety.

This application also claims benefit of U.S. Provisional Application Ser. No. 61/301,205, filed Feb. 4, 2010 (Attorney Docket No. APPM/14998L02), which is incorporated by reference in its entirety.

This application is related to U.S. patent application Ser. No. 29/353,504, filed Jan. 9, 2010 (Attorney Docket No. APPM/15040), which is incorporated by reference in its entirety.

### BACKGROUND OF THE INVENTION

1. Field of the Invention

Embodiments of the present invention generally relate to a gas distribution showerhead having insulated corner regions.

2. Description of the Related Art

Plasma enhanced chemical vapor deposition (PECVD) is generally employed to deposit thin films on substrates, such as semiconductor substrates, solar panel substrates, flat panel display (FPD) substrates, organic light emitting display (OLED) substrates, and other substrates. PECVD is a deposition method whereby processing gas is introduced into a processing chamber through a gas distribution showerhead. The showerhead spreads out the processing gas as it flows into a processing space between the showerhead and a susceptor supporting a substrate. The showerhead is electrically biased with an RF current to ignite the processing gas into a plasma. The susceptor, sitting opposite to the showerhead, is electrically grounded and functions as an anode. The plasma reacts to form a thin film of material on a surface of the substrate that is positioned on the susceptor.

In large area, PECVD chambers, the showerheads are generally rectangular in shape to correspond with substantially rectangular shaped substrates. As a result, the showerheads have corner regions in which RF current concentrates, resulting in arcing between the corner regions of the showerhead and the walls of the chamber. Further, the RF current concentration in the corner regions of the showerhead tends to result in uneven dissociation of ions in the generated plasma and uneven film deposition on the substrate.

Therefore, improved gas distribution showerheads are needed for PECVD chambers.

### SUMMARY OF THE INVENTION

In one embodiment of the present invention, a gas distribution showerhead comprises a showerhead body having a plurality of gas passages extending therethrough and an insulated member attached to a corner region of the showerhead body.

In another embodiment of the present invention, a plasma enhanced chemical vapor deposition apparatus comprises a chamber body, a substrate support disposed within the chamber body having a substrate support surface for receiving a substrate, a gas distribution showerhead disposed in the chamber body opposite the substrate support, the gas distribution showerhead having a showerhead body with a plurality of gas passages passing therethrough and a plurality of corner regions, and an insulated member attached to the gas distribution showerhead in each corner region of the gas distribution showerhead.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view of a PECVD chamber according to one embodiment.

FIG. 2 is a schematic plan view of the gas distribution showerhead according to one embodiment of the present invention.

FIG. 3 is a schematic cross-sectional view of the gas distribution showerhead depicted in FIG. 2 taken along lines 3-3.

FIG. 4 is a schematic plan view of the gas distribution showerhead according to another embodiment of the present invention.

FIG. 5 is a schematic cross-sectional view of the gas distribution showerhead depicted in FIG. 4 taken along lines 5-5.

FIG. 6 is a partial perspective view of another embodiment of a gas distribution plate of the present invention with one corner enlarged.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to a gas distribution showerhead having insulated corner regions to reduce arcing and improve deposition uniformity control. In one embodiment, the gas distribution showerhead is formed of a conductive material having a polygonal plane form defined by substantially vertical corner regions. The corner members may be made of a material having electrical insulating properties, such as a ceramic or insulating polymer. In some embodiments, the gas distribution showerhead is substantially rectangular, having the material removed from the corner regions. Corner members attached to the conductive showerhead are formed substantially in the shape of the material removed from corner regions.

The invention is described below in relation to a PECVD apparatus available from AKT America, Inc., a subsidiary of Applied Materials, Inc., Santa Clara, Calif. It is to be understood that the invention has applicability in other chambers as well, including PECVD apparatus available from other manufacturers.

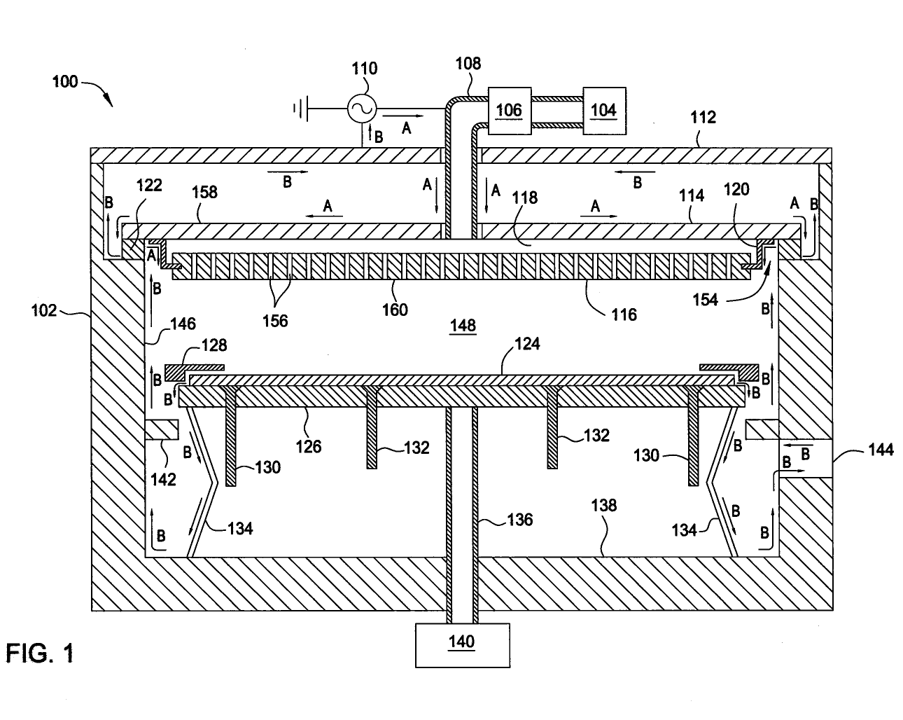

FIG. 1 is a schematic cross sectional view of a PECVD chamber 100 according to one embodiment. The chamber 100 includes a chamber body 102, into which processing gas is fed from a gas source 104. When the chamber 100 is used for deposition, the processing gas is fed from the gas source 104, through a remote plasma source 106 and through a tube 108. The processing gas is not ignited into a plasma in the remote plasma source 106. During cleaning, the cleaning gas is sent from the gas source 104 into the remote plasma source 106 where it is ignited into a plasma before entering the chamber 100. The tube 108 is an electrically conductive tube.

The RF current that is used to ignite the processing gas into a plasma within the chamber 100 is coupled to the tube 108 from an RF power source 110. RF current travels along the outside of the tube 108 due to the ‘skin effect’ of RF current. RF current penetrates only a certain, predeterminable depth into a conductive material. Thus, the RF current travels along the outside of the tube 108 and the processing gas travels within the tube 108. The processing gas is not excited by the RF current when it is traveling in the tube 108 because the RF current does not penetrate far enough into the tube 108 to expose the processing gas to RF current when it is within the tube 108.

The processing gas is fed to the chamber 100 through the backing plate 114. The processing gas then expands into an area 118 between the backing plate 114 and the showerhead 116. The processing gas then travels through gas passages 156 and into the processing area 148.

The RF current, on the other hand, does not enter the area 118 between the backing plate 114 and the showerhead 116. Instead, the RF current travels along the outside of the tube 108 to the backing plate 114. There, the RF current travels along the atmospheric side 158 of the backing plate 114. The backing plate 114 may be formed from a conductive material, such as aluminum or stainless steel. The RF current travels from the backing plate 114 along a bracket 120 made of a conductive material, such as aluminum or stainless steel. The RF current then travels along the front face 160 of the showerhead 116 where it ignites the processing gas that has passed through the gas passages 156 into a plasma in the processing area 148 located between the showerhead 116 and the substrate 124. The path that the RF current travels to reach the downstream side 160 of the showerhead 116 is shown by arrows “A”. In one embodiment, the showerhead 116 is made of a conductive material, such as aluminum or stainless steel.

Due to the plasma generated in the processing area 148, material is deposited onto the substrate 124. The substrate 124 may be disposed on a susceptor 126 that is movable between a first position and a second position. The susceptor 126 may be disposed on a stem 136 and be moved by an actuator 140.

The substrate 124 may be a large area substrate and hence, may bow when elevated on lift pins 130, 132. Thus, the lift pins 130, 132 may have different lengths. When the substrate 124 is inserted into the chamber through the slit valve opening 144, the susceptor 126 may be in a lowered position. When the susceptor 126 is in a lowered position, the lift pins 130, 132 may extend above the susceptor 126. Thus, the substrate 124 is placed on the lift pins initially. The lift pins 130, 132 have different lengths. The outer lift pins 130 are longer than the inner lift pins 132 so that the substrate 124 sags in the center when placed on the lift pins 130, 132. The susceptor 126 is raised to meet the substrate 124. The substrate 124 contacts the susceptor 126 in a center to edge progression so that any gas that is present between the susceptor 126 and the substrate 124 is expelled. The lift pins 130, 132 and then raised by the susceptor 126 along with the substrate 124.

When the susceptor 126 is raised above the slit valve opening 144, the susceptor 126 may encounter a shadow frame 128. The shadow frame 128, when not in use, rests on a ledge 142 positioned above the slit valve opening 144. The shadow frame 128 shields areas of the susceptor 126 that are not covered by a substrate 124 from deposition. Additionally, the shadow frame 128, when it comprises an electrically insulating material, may electrically shield the RF current that travels along the susceptor 126 from the RF current that travels along the walls 146. In one embodiment, the shadow frame 128 may comprise an insulating material, such as Al₂O₃.

The RF current couples through the plasma to the susceptor 126. In one embodiment, the susceptor 126 may comprise a conductive material such as aluminum or stainless steel. The RF current travels back to the power source 110 by traveling the path shown by arrows “B”.

To shorten the RF current return path, one or more straps 134 may be coupled to the susceptor 126. By utilizing straps 134, the RF current travels down the straps to the bottom 138 of the chamber and then back up the walls 146 of the chamber. In other embodiments, RF return path elements may be coupled between the susceptor 126 and the shadow frame ledge 142 as well to shorten the RF current return path. In the absence of the straps 134, the RF current travels along the bottom of the susceptor 126, down the stem 136 and then back along the bottom 138 and walls 146 of the chamber.

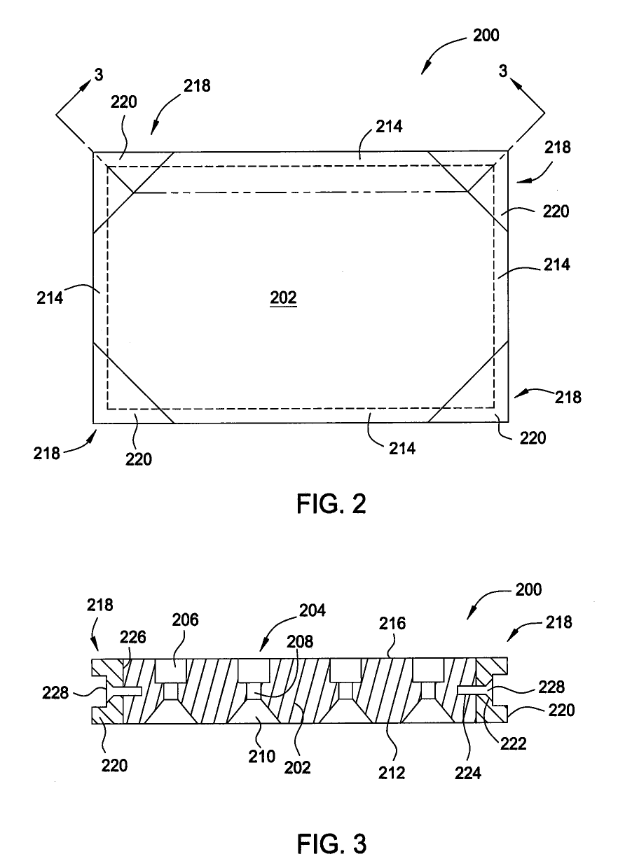

The RF current returns back along the wall 146 and the lid 112 before reaching the power source 110. An isolator 122, such as an insulator and o-ring seal, electrically isolates the wall 146 from the backing plate 114. Arcing may occur between the showerhead 116 and the wall 146 in area 154 to the high potential difference, particularly in corner regions (identified with reference numeral 218 in FIG. 2) of the showerhead 116.

FIG. 2 is a schematic plan view of the gas distribution showerhead 200 according to one embodiment of the present invention. FIG. 3 is a schematic cross-sectional view of the gas distribution showerhead 200 depicted in FIG. 2 taken along lines 3-3.

In one embodiment, the showerhead 200 has a showerhead body 202 with a plurality of gas passages 204 (not shown in FIG. 2) passing between an upstream side 218 and a downstream side 212 thereof. In the embodiment depicted in FIG. 3, both the downstream side 212 and the upstream side 218 are depicted as being planar. The downstream side 212 and the upstream side 218 may be rectangular and coupled by edges 226. The edges 226 meet in the corner regions 218 (e.g., the vertical corners) to define the lateral extent of the planar rectangular showerhead body 202. In other embodiments, the downstream side 212 and/or the upstream side 218 may be concave or convex. The gas passages 204 depicted in FIG. 3 have an upper cylindrical region 206, an orifice 208, and a hollow cathode cavity 210. The orifice 208 generates a back pressure on the upstream side 218 of the showerhead 200. Due to the back pressure, processing gas may be more evenly distributed on the upstream side 218 of the showerhead 200 before passing through the gas passages 204. The hollow cathode cavity 210 permits plasma to be generated within the gas passage 204, allowing greater control of plasma distribution. The showerhead 200 includes a flange 214 that extends outwardly around the perimeter of the showerhead body 202.

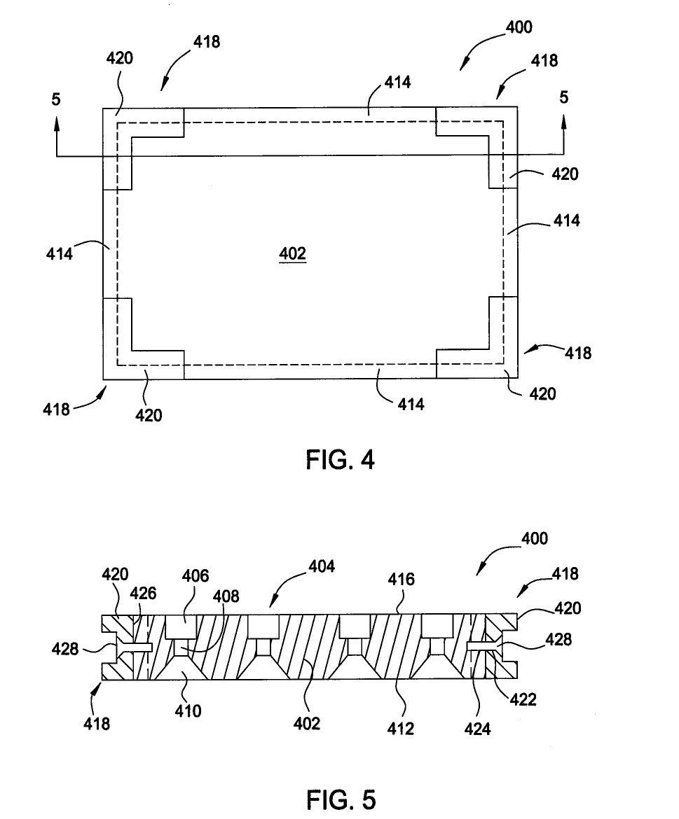

In one embodiment, the showerhead body 202 is formed of a conductive material, such as aluminum or stainless steel, with a portion of corner regions 218 removed. In the embodiment shown in FIG. 2, a portion of the body 202 removed from corner region 218 is substantially in the shape of a triangle. However, according to other embodiments, the material from corner region 218 may be removed in other shapes, such as a rectangular shape or an “L” as subsequently shown and described with respect to FIG. 4.

In one embodiment, a corner flange member 220 is attached to the showerhead body 202 in each of the corner regions 218. The corner flange member 220 has a curved or rounded outer surface exposed to the processing area 148. In one embodiment, the corner flange members 220 are made of an insulating material, such as a ceramic material. In one embodiment, the corner flange members 220 are made of an insulating polymer material, such as polytetrafluoroethylene (PTFE). The corner flange members 220 are made of insulating materials in order to prevent RF current concentration in the corner regions 218 of the showerhead 200. By preventing RF current concentration in the corner regions 218 of the showerhead 200, arcing between the showerhead 200 and the chamber body 102 (FIG. 1) is prevented in the corner regions 218. Additionally, by preventing RF current concentration in the corner regions 218 of the showerhead 200, the plasma density at the corner regions 218 may be better controlled, resulting in more uniform deposition of material on the substrate 124 (FIG. 1). In another embodiment, the corner flange member 220 is made of a dielectric material disposed between the corner regions 218 of the showerhead and a grounded surface on the RF current return path described above.

In one embodiment, each corner flange member 220 has one or more apertures 222 formed therethrough configured to match threaded blind holes 224 formed in edges 226 of the showerhead body 202 facing the corner regions 218. In one embodiment, each corner flange member 220 is attached to the showerhead body 202 using fasteners 228. In other embodiments, the corner flange members 220 may be bonded to the edges 226 of the showerhead body 202 facing the corner regions 218 via an appropriate adhesive or other suitable bonding technique.

FIG. 4 is a schematic plan view of a showerhead 400 according to another embodiment. FIG. 5 is a schematic cross-sectional view of the showerhead 400 in FIG. 4 taken along line 5-5.

In one embodiment, the showerhead 400 has a showerhead body 402 with a plurality of gas passages 404 (not shown in FIG. 4) passing between an upstream side 416 and a downstream side 412 thereof. In the embodiment depicted in FIG. 5, both the downstream side 412 and the upstream side 416 are depicted as being planar. In other embodiments, the downstream side 412 and/or the upstream side 416 may be concave or convex. The gas passages 404 depicted in FIG. 5 have an upper cylindrical region 406, an orifice 408, and a hollow cathode cavity 410. The showerhead 400 includes a flange 414 that extends outwardly around the perimeter of the showerhead body 402.

In one embodiment, the showerhead body 402 is formed of a conductive material, such as aluminum or stainless steel, with material from the corner regions 418 removed. In the embodiment shown in FIG. 4, the material removed from the corner region 418 is removed in an “L” shape.

In one embodiment, a corner flange member 420 is attached to the showerhead body 402 in each of the corner regions 418. In one embodiment, the corner flange members 420 have “L” shape and are made of an insulating material, such as a ceramic material. In one embodiment, the corner flange members 420 are made of an insulating polymer material, such as polytetrafluoroethylene (PTFE). The corner flange members 420 are made of insulating materials in order to prevent RF current concentration in the corner regions 418 of the showerhead 400. By preventing RF current concentration in the corner regions 418 of the showerhead 400, arcing between the showerhead 400 and the chamber body 102 (FIG. 1) is prevented in the corner regions 418. Additionally, by preventing RF current concentration in the corner regions 418 of the showerhead 400, the plasma density at the corner regions 418 may be better controlled, resulting in more uniform deposition of material on the substrate 124 (FIG. 1).

In one embodiment, each corner flange member 420 has one or more apertures 422 formed therethrough configured to match threaded blind holes 424 formed in edges 426 of the showerhead body 402 facing the corner regions 418. In one embodiment, each corner flange member 420 is attached to the showerhead body 402 using fasteners 428. In other embodiments, the corner flange members 420 may be bonded to the edges 426 of the showerhead body 402 facing the corner regions 418 via an appropriate adhesive or other suitable bonding technique.

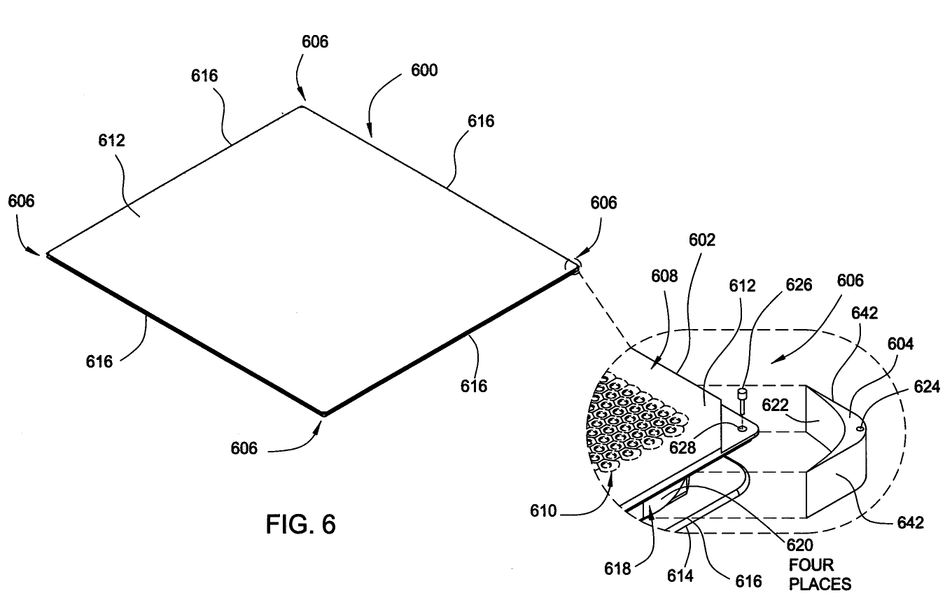

FIG. 6 is a partial perspective view of another embodiment of a gas distribution plate 600 having one corner region enlarged and exploded. The gas distribution plate 600 includes a conductive plate 602 having a plurality of dielectric inserts 604. The dielectric inserts 604 may be coupled to the conductive plate 602 in locations that provide at least one of the following benefits when used in a plasma process in a vacuum processing chamber: changing the electric field utilized to sustain a plasma below the conductive plate 602, thereby providing a process control knob; and reducing charge concentration at corner regions 606 of the conductive plate 602 to prevent arcing. The dielectric material also provides an electrostatic barrier between the conductive plate 602 and a grounded surface (e.g. a chamber wall 146) on the RF current return path described above. In one embodiment, the conductive plate 602 is fabricated from aluminum, while the dielectric inserts 604 are fabricated from ceramic.

The conductive plate 602 includes a body 608 through which a plurality of gas distribution holes 610 are formed providing a gas passages between a top surface 612 and a bottom surface 614 of the plate 602. An edge 616 of the plate 602 has a recessed surface 618 that extends circumferentially around the perimeter of the plate 602 such that the top surface 612 and the bottom surface 614 of the body 608 extend beyond the recessed surface 618. The edge 616 has a radius 620 at the corner regions 606 of the conductive plate 602 such that charges are not accumulated at the corner regions 606 of the edge 616 when RF power is applied to the gas distribution plate 600.

The dielectric insert 604 has a substantially triangular form, with two exterior sides 642 and an interior side 622. The exterior sides 642 are disposed orthogonal to each other, while the interior side 622 has a curvature that mates with the curvature of the radius 620. It is contemplated that the exterior sides 642 may be joined by a curved region having a curvature about or equivalent to the radius 620 of the corner region 606. The dielectric insert 604 includes a hole 624 formed proximate the intersection of the exterior sides 642. A pin 626 is utilized to couple the dielectric insert 604 to the body 608. The pin 626 may be fabricated from ceramic, dielectric or metal material, and may be a pin, bolt, screw, rivet or other suitable fastener. The pin 626 is passed through the dielectric insert 604 and a hole 628 formed in the top surface 612 of the conductive plate 602 that locks the insert 604 against the recessed surface 618 between the top surface 612 and the bottom surface 614 of the body 608. In this position, the exterior sides 642 of the dielectric insert 604 do not extend beyond the edge 616.

It is contemplated that dielectric insert 604 may be alternatively utilized to only comprise the top surface 612, to only comprise the bottom surface 614, or to comprise any portion of the corner regions 606.

By having insulating members disposed in the corner regions of the showerhead, RF concentration in the corner regions is prevented. Preventing RF concentration in the corner regions, in turn, substantially reduces arcing between the showerhead and the chamber body. Additionally, preventing RF concentration in the corner regions provides more uniform plasma density and, as a result, more uniform deposition on the substrate disposed in the PECVD chamber.

While the foregoing is directed to embodiments of the present invention, other and further embodiments of the invention may be devised without departing from the basic scope thereof, and the scope thereof is determined by the claims that follow.

1. A gas distribution showerhead, comprising:
a showerhead body having a plurality of gas passages extending therethrough; and
an insulated member attached to a corner region of the showerhead body in thereof.

2. The gas distribution showerhead of claim 1, wherein the insulated member is a corner flange member, the corner flange member covering adjacent edges of the showerhead body.

3. The gas distribution showerhead of claim 2, wherein the corner flange member has a curved outer surface.

4. The gas distribution showerhead of claim 2, wherein the insulated member is comprised of a ceramic material.

5. The gas distribution showerhead of claim 2, wherein the insulated member is comprised of an insulating polymer material.

6. The gas distribution showerhead of claim 2, wherein the insulated member is comprised of a dielectric material.

7. The gas distribution showerhead of claim 1, wherein the insulated member is disposed in a recessed surface formed in an edge of the showerhead body.

8. The gas distribution showerhead of claim 7 further comprising:
a pin extending through the showerhead body and into the insulated member.

9. A plasma enhanced chemical vapor deposition apparatus, comprising:
a chamber body;
a substrate support disposed within the chamber body having a substrate support surface for receiving a substrate;
a gas distribution showerhead disposed in the chamber body opposite the substrate support, the gas distribution showerhead having a showerhead body with a plurality of gas passages passing therethrough and a plurality of corner regions; and
an insulated member attached to the gas distribution showerhead in each corner region of the gas distribution showerhead, the insulated members disposed between the showerhead body and the chamber body.

10. The apparatus of claim 9, wherein each insulated member adjacent edges of the showerhead body that meet in the corner region.

11. The apparatus of claim 9, wherein each insulated member is comprised of a ceramic material.

12. The apparatus of claim 9, wherein each insulated member is comprised of an insulating polymer material.

13. The apparatus of claim 9, wherein each insulated member comprises a dielectric material disposed between a vertical corner defined in each corner region and a grounded surface of the chamber body.

14. A plasma enhanced chemical vapor deposition apparatus, comprising:
a chamber body;
a substrate support disposed within the chamber body having a substrate support surface for receiving a substrate;
a gas distribution showerhead disposed in the chamber body opposite the substrate support, the gas distribution showerhead having a showerhead body defined by four with a plurality of gas passages passing therethrough, the showerhead body having a rectangular lower surface coupling four edges, the edges meeting at corner regions; and
four insulated members attached to the gas distribution showerhead, each insulated member covering a respective one of the corners of the showerhead body, the insulated members disposed between the showerhead body and the chamber body.

15. The apparatus of claim 14, wherein each insulated member is comprised of a ceramic material.

16. The apparatus of claim 14, wherein each insulated member is comprised of an insulating polymer material.

17. The gas distribution showerhead of claim 14, wherein each insulated member is disposed in a recessed surface formed in the showerhead body.

18. The gas distribution showerhead of claim 17 further comprising:
a pin extending through the showerhead body and into the insulated member.

19. The gas distribution showerhead of claim 14 further comprising:
a pin extending through the showerhead body and into one of the insulated members.
